(19) United States
(12) Patent Application Publication
(10) Pub. No.: US 2022/0115362 A1
(43) Pub. Date: Apr. 14, 2022

(54) SCALABLE HIGH-PERFORMANCE PACKAGE ARCHITECTURE USING PROCESSOR-MEMORY-PHOTONICS MODULES

(71) Applicant: Intel Corporation, Santa Clara, CA (US)

(72) Inventors: Debendra MALLIK, Chandler, AZ (US); Ravindranath MAHAJAN, Chandler, AZ (US); Dipankar DAS, Pune (IN)

(21) Appl. No.: 17/067,069

(22) Filed: Oct. 9, 2020

(51) Int. Cl. H01L 25/16; H01L 23/32; H05K 7/10; G02B 6/42

(52) U.S. Cl. CPC H01L 25/167; G02B 6/425; H05K 7/1084; H01L 23/32

(57) ABSTRACT

A processor package module comprises a processor-memory stack including one or more compute die stacked and interconnected with a memory stack on a substrate. One or more photonic die is on the substrate to transmit and receive optical I/O, the one or more photonic die connected to the processor-memory stack and connected to external components through a fiber array. The substrate is mounted into a socket housing, such as a land grid array (LGA) socket. An array of processor package modules are interconnected on a processor substrate via fiber arrays and optical connectors to form a processor chip complex.

### TECHNICAL FIELD

Embodiments of the disclosure are in the field of integrated circuit structures, and in particular, a scalable high-performance package architecture using processor-memory-photonics modules.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips.

For example, increased densities have led to high-performance system on a chip (SOC). Some high-performance systems may be dedicated to artificial intelligence (AI), which require more than wafer size compute die with high bandwidth interconnections to high capacity memory. This has led some companies to use a 300 mm wafer as single chip (215 mm×215 mm square die). Such a large die not only has significant process yield problems, it also creates various other problems such as: (a) very long (10 s to 100 s mm long) on-die interconnect lengths to access far end memory locations, (b) reticle stitching to connect circuits in the neighboring reticle, (c) the need for complex schemes to bypass defective circuit areas. Consequently, such architectures can lead to difficulties during manufacturing and may be difficult to scale.

### BRIEF DESCRIPTION OF THE DRAWINGS

FIGS. 1A and 1B depict a top view and a cross-section view of a semiconductor package structure in accordance with one or more embodiments.

FIGS. 1C-1F depict angled views of the processor-memory stack showing architectural embodiments.

FIG. 2 depicts a cross-section view of the processor package module once mounted to a socket housing.

FIG. 3A is a diagram illustrating a top view of a processor chip complex.

FIGS. 3B-3D are diagrams illustrating cross-section views of the processor chip complex.

FIG. 4 is a diagram illustrating a process flow for fabricating a processor chip complex in accordance with an embodiment of the present disclosure.

FIG. 5 illustrates a computing device in accordance with one implementation of the disclosure.

### DESCRIPTION OF THE EMBODIMENTS

Scalable high-performance package architectures using processor-memory-photonics modules are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments of the disclosure are directed to a processor-memory-photonics module, referred to herein as a processor package module, comprising a processor-memory stack that includes one or more compute die stacked and interconnected with a memory stack on a substrate. One or more photonic die is on the substrate to transmit and receive optical I/O. The photonic die are connected to the processor-memory stack and connected to external components through a fiber array. The substrate is mounted into a socket housing, such as a land grid array (LGA) socket. In a further embodiment, an array of such processor package modules may be mounted on a processor board, where adjacent processor package modules are interconnected through their respective photonic die, fiber arrays and optical connectors to form a chip processor complex. The processor package modules and the chip processor complex may be fabricated using the methods as disclosed herein. In addition, each of the processor package modules may be pretested prior to mounting and being and optically connected to form the processor chip processor complex.

The disclosed embodiments provide an alternate packaging and systems architecture for a cost effective, manufacturable and a fundamentally more scalable solution compared to conventional high-performance systems. The chip processor complex comprising an array of optically connected pretested processor package modules may be applicable to AI processing, high-performance high-bandwidth computing, 3D stacking technology and scalable architectures to provide high-bandwidth connectivity.

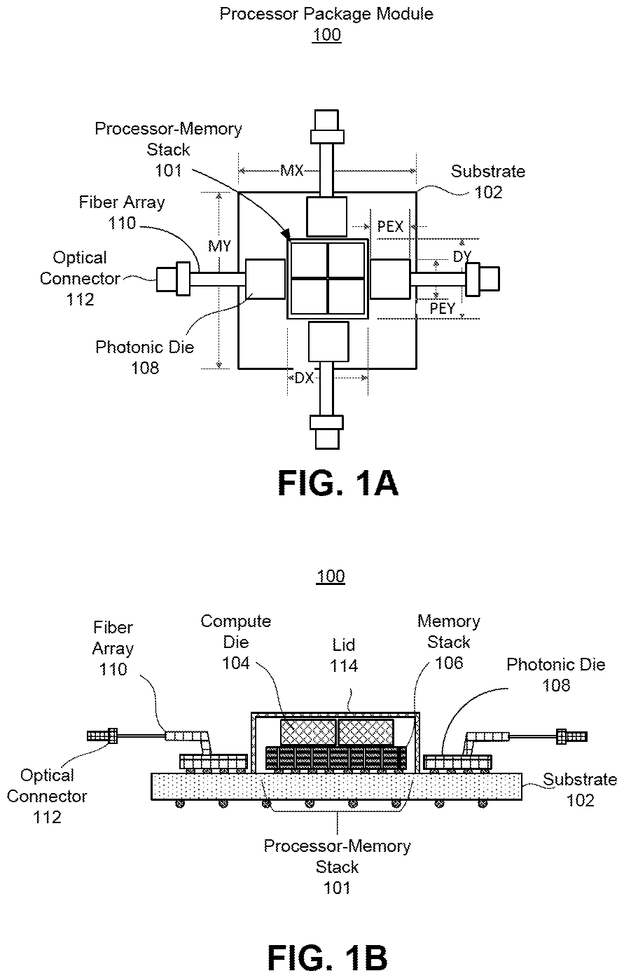

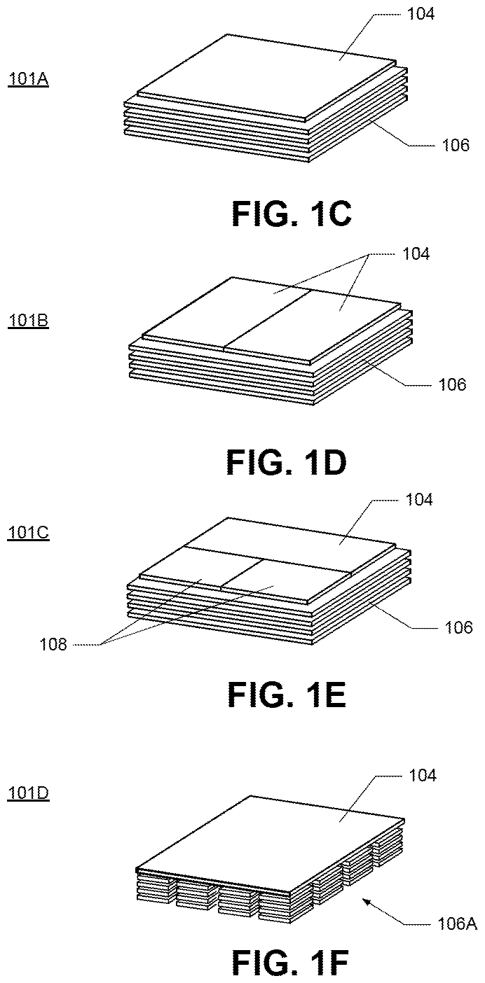

FIGS. 1A and 1B depict a top view and a cross-section view of a semiconductor package structure in accordance with one or more embodiments. The semiconductor package comprises a processor-memory-photonics module, referred to herein as a processor package module 100. More specifically, the processor package module 100 includes a processor-memory stack 101 comprising one or more compute die 104 stacked and interconnected with a memory stack 106 on a substrate 102. The memory stack comprises stacked memory dies, such a stacked ADM die cube or a 3D DRAM cube, for example, to form a processor-memory stack. In one embodiment, the memory stack may comprise a monolithic memory die, such as an SRAM or a standard or custom DRAM. The substrate 102 may comprise any type of substrate known in the art. For example, an organic substrate, an inorganic substrate (e.g., ceramic substrate, silicon substrate, etc.), a combination of an organic substrate and an inorganic substrate, etc.

According to one aspect of the disclosed embodiments, one or more photonic die 108 are mounted to the substrate 102 along with the processor memory stack 101 to transmit and receive optical I/O. For example, in one embodiment, the photonic die 108 may provide a Terabit/s optical physical layer to support high-bandwidth, low-latency connectivity. In one embodiment, the photonic die 108 refers to a single die. In another embodiment, the term photonic die 108 is included in a photonic multi-chip-package with laser and electronic control chips. The photonic dies 108 are connected to the processor-memory stack 101 and connected to external components (not shown) through optical connections, which may comprise one or more fiber arrays 110 and corresponding optical connectors 112. An off-chip laser source provides optical signals through the optical connectors 112, as explained below.

In one embodiment, the compute dies 104 are stacked over the memory stack 106, but in another embodiment, the memory stack 106 is stacked over the compute die 104. In embodiments, the compute die 104, the memory stack 106, and the photonic die 108 may be connected through interconnects embedded into the substrate 102. In one embodiment, an optional lid 114 or a heat shield may be placed over at least the processor-memory stack 101.

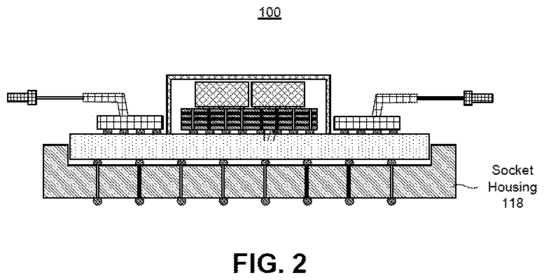

The compute die 104 may be mounted to the memory stack 106, and the memory stack 106 may be mounted to the substrate 102 through microbumps or other contacts. The photonic die 108 may be also mounted to the substrate 102 through micro-bumps or other contacts. The substrate 102, in turn, may be mounted to the socket housing 118, as shown in FIG. 2, through microbumps, or large pitch bumps. In one embodiment, the microbumps and large pitch bumps may comprise plated copper or tin.

In one embodiment, the photonic dies 108 are mounted on the substrate 102 adjacent to the processor-memory stack 101. FIG. 1A shows an embodiment where multiple photonic dies 108 surround the processor-memory stack 101 on the substrate 102. More specifically, FIG. 1A shows an embodiment where a respective photonic die 108 is mounted to the substrate 102 adjacent to each of the four sides of the processor-memory stack 101 for a total of four photonic die 108. However, many variations are possible. As other examples, multiple photonic dies 108 may be located on the same side of the substrate and/or the same or a different number of photonic dies 108 may be mounted to the substrate 102 on different sides, and each side of the substrate 102 need not include one of the photonic die 108. In one embodiment, the photonic die 108, the fiber arrays 110 and optical connectors 112 may comprise a TeraPhY™ line of products from Ayar Labs™.

Other embodiments exist for the processor-memory stack 101. For example, FIGS. 1C-1F depict angled views of the processor-memory stack 101 showing architectural embodiments. FIG. 1C shows an embodiment where the processor-memory stack 101A comprises a single large compute die 104 over the memory stack 106. FIG. 1D shows another embodiment where the processor-memory stack 101B comprises two side-by-side compute die 104 over the memory stack 106, which is similar to FIG. 1A showing an array of four compute die 104. FIG. 1E shows an embodiment where the processor-memory stack 101C comprises a single compute die 104 with one or more photonic die 108 mounted adjacent to the compute die 104 over the memory stack 106, rather than mounted to the board 102 as shown in FIG. 1A. FIG. 1F shows an embodiment where the process-memory stack 101D comprises a single compute die 104 over an array of stacked memory die cubes 106A.

In one embodiment, the processor package module 100 may have a maximum size equal to a full reticle size, but may be smaller. As shown in FIG. 1A, at full reticle size, the processor-memory stack 101 may have DX and DY dimensions of 33 and 25 mm, respectively; the photonic die 108 may have PEX and PEY dimensions of 8 and 9 mm respectively; and the substrate 102 may have MX and MY dimensions of 33 and 25 mm.

Referring now to FIG. 2, a cross-section view of the processor package module 100 is shown once mounted to a socket housing 118. In one embodiment, a socket housing 118 comprises a land grid array (LGA) socket to provide a LGA processor package module.

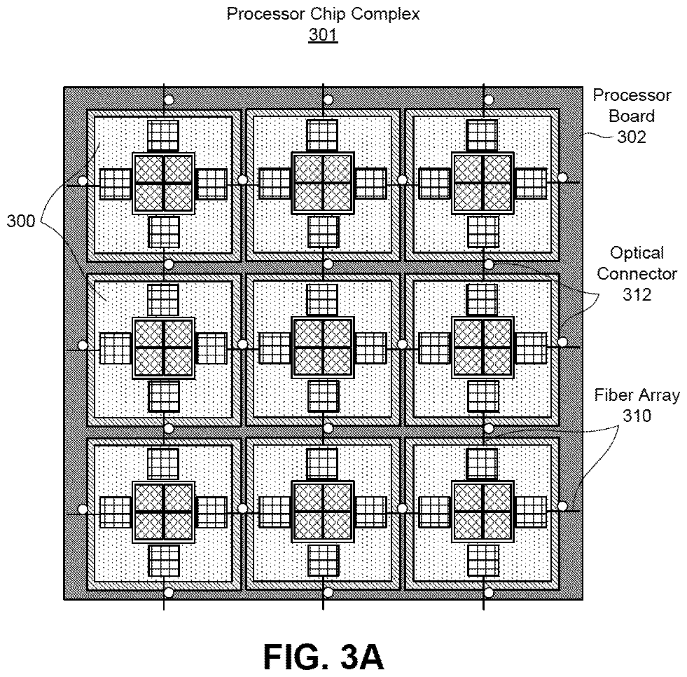

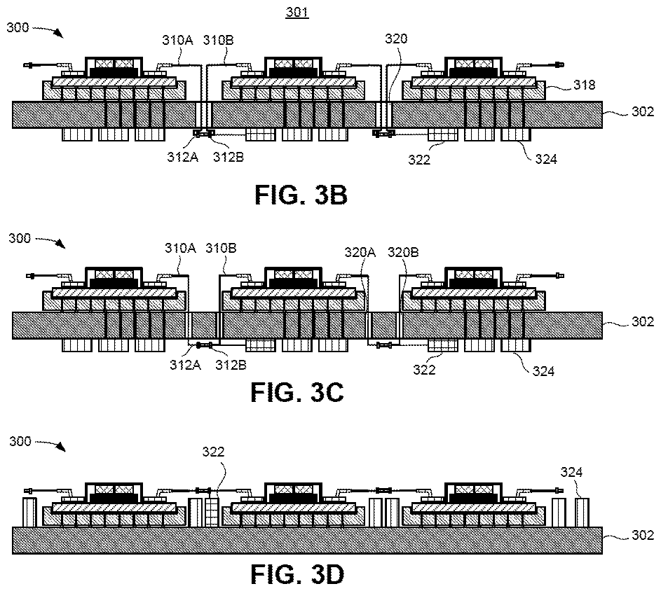

According to a further aspect of the disclosed embodiments, a processor chip complex is created by optically interconnecting an array of the processor package modules onto a processor board, as shown in FIGS. 3A-3D.

FIG. 3A is a diagram illustrating a top view of a processor chip complex. As depicted, the processor chip complex 301 comprises an array of processor package modules 300 mounted to a processor board 302. According to an aspect of the disclosed embodiments, the processor package modules 300 are optically coupled to adjacent processor package modules 300 in the array using the optical connectors 312 and fiber arrays 310.

As described above with respect to FIG. 1A, the processor package modules 300 comprise a processor-memory stack comprising one or more compute die that is stacked and interconnected with a memory stack on a substrate. Photonic die are on the substrate and connected to the processor-memory stack to transmit and receive optical I/O. Each of the photonic die is coupled to a respective fiber array 310 and optical connector 312. The substrate 302 is mounted into a socket housing, such as a LGA socket, and the socket is mounted to a front side of the processor board 302.

The processor chip complex 301 thus provides an array of optically interconnected processor package modules 300 (or LGA package modules in one embodiment). The example shown in FIG. 3A illustrates a 3×3 array, but any number of processor package modules 300 may be added to scale to a very large processor system with various levels of performance depending on the number of processor package modules 300 used. It should be understood that each of the processor package modules 300 are separately testable prior to mounting on the processor board 302. In this regard, since the processor package modules 300 are socketed, the processor package modules 300 are easily field replaceable. In addition the processor package modules 300 may be designed to be reused in existing LGA sockets.

FIGS. 3B-3D are diagrams illustrating cross-section views of the processor chip complex 301. As shown in FIG. 3B, the array of processor package modules 300 are mounted to a front side of the processor board 302, while in one embodiment, the optical connectors 312A and 312B of adjacent ones of the processor package modules 300 are coupled together on a backside of the processor board 302. In this embodiment, the fiber arrays 310A and 310B of the adjacent processor package modules 300 are routed from the front side of the processor board 302 to the backside of the processor board 302 through holes 320 in the processor board 302.

FIG. 3B shows an embodiment where the processor board 302 includes a single hole 320 between two adjacent processor package modules 300 to route the fiber arrays 310A and 310B to the backside of the processor board 302.

FIG. 3C shows an embodiment where the processor board 302 includes two holes 320A and 320B between two adjacent processor package modules 300. The first holes 320A routes the fiber array 310A from one of the two adjacent processor package modules, and the second hole 320B routes the fiber array 310B from the second of the two adjacent processor package modules 300.

Both FIGS. 3B and 3C also show that in one embodiment, the processor chip complex 301 further includes at least one off-chip laser source 322 mounted to the processor board 302 to supply optical signals to the processor package modules 300. The processor chip complex 301 further includes at least one power supply 324 to supply power to the processor package modules 300. In one embodiment, the laser source 322 and the power supply 324 are mounted to a backside of the processor board 302, as shown in FIGS. 3B and 3C. Power signals may be transmitted from the power supply 324 to the socket housing 318 of the processor package modules 300 using vias or through holes embedded in the processor board 302.

FIG. 3D shows an embodiment where the laser source 322 and the power supply 324 are mounted to a front side of the processor board 302 between the processor modules 300. In another embodiment, the laser source 322 and the power supply 324 may be mounted on opposite sides of the processor board 302.

The architecture of the processor package module 100 and the processor chip complex 300 provides many advantages. One advantage is size. The processor package module 100 is significantly smaller than wafer size die, enabling ease of module manufacturing and ease of replacing any module within the system. Another advantage is after fabrication, each processor package module 100 can be pre-tested resulting in field replaceable modules. The processor package modules 100 are also easily scalable for combined use in very large AI processor systems. The processor package modules 100 have a low fabrication cost because of the use of known good die (KGD), i.e, the compute die 104 (either reticle size die or even smaller chiplets increases die yield). Similarly, the use of known good stack die (KGSD), i.e., the memory stack 106, enables high yield of the processor chip complex 300. Finally, various versions of the processor chip complexes with different levels of performance can be fabricated by using large or small arrays of the processor package modules 100.

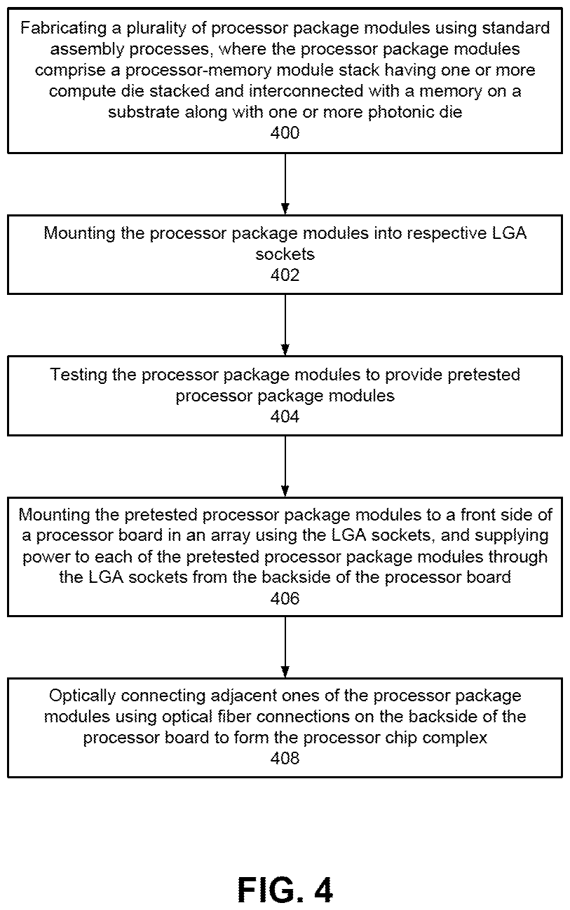

As an exemplary processing scheme involving fabrication of a scalable high-performance processor chip complex package architecture comprising an array processor package modules, refer to FIG. 4.

FIG. 4 is a diagram illustrating a process flow for fabricating a processor chip complex in accordance with an embodiment of the present disclosure. The process may begin by fabricating a plurality of processor package modules using standard assembly processes, where ones of the processor package modules comprise a processor-memory module stack having one or more compute die stacked and interconnected with a memory on a substrate, and one or more photonic die (block 400). The processor package modules are mounted into respective LGA sockets (block 402). Before and/or after the processor package modules are mounted to the LGA sockets, the processor package modules are tested to provide pretested processor package modules (block 404). Any type of standard testing procedures may be performed such as stress testing, performance testing, electrical testing, and the like. The pretested processor package modules are mounted to a front side of a processor board in an array using the LGA sockets, and power is supplied to each of the pretested processor package modules through the LGA sockets from a backside of the processor board (block 406). In an alternative embodiment, power may be supplied from the front side of the processor board. Adjacent ones of the pretested processor package modules are optically connected using optical fiber connections on the backside of the processor board to form the processor chip complex (block 408). In another embodiment, the optical fiber connections are made on the front side of the processor board. The processor chip complex is then tested. Before or after testing, optical fiber connections are made between at least a portions of the processor package modules located along one or more edges of the array to components external to the processor chip complex. A method has been described for fabricating a processor chip complex that is co-packaged with an array of processor package modules, each comprising a processor-memory stack and photonics.

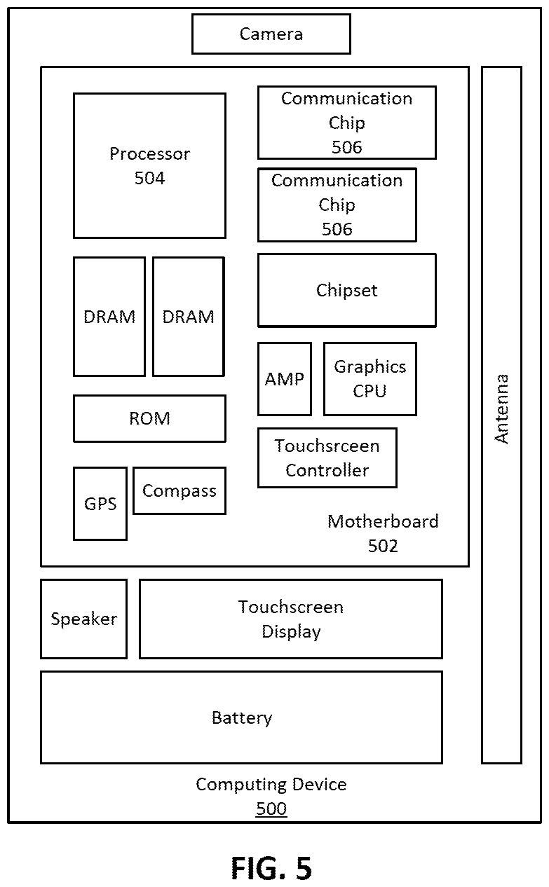

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

Depending on its applications, computing device 500 may include other components that may or may not be physically and electrically coupled to the board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others. The communication chip 506 includes an integrated circuit die packaged within the communication chip 506

The processor 504 of the computing device 500 includes an integrated circuit die packaged within the processor 504. In some implementations of the disclosure, the processor 504 may comprise processor chip complex in accordance with implementations of embodiments of the disclosure. The term “processor” may refer to any device or portion of a device that processes electronic data from registers and/or memory to transform that electronic data into other electronic data that may be stored in registers and/or memory.

In further implementations, another component housed within the computing device 500 may contain processor chip complex in accordance with implementations of embodiments of the disclosure.

In various implementations, the computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Thus, embodiments described herein include a scalable high-performance package architecture using processor-memory-photonics modules.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example embodiment 1: A processor package module comprises a processor-memory stack including one or more compute die stacked and interconnected with a memory stack on a substrate. One or more photonic die is on the substrate to transmit and receive optical I/O, the one or more photonic die connected to the processor-memory stack and connected to external components through a fiber array. The substrate is mounted into a socket housing, such as a land grid array (LGA) socket. An array of processor package modules are interconnected on a processor board via fiber arrays and optical connectors to form a processor chip complex.

Example embodiment 2: The processor package module of embodiment 1, wherein the one or more compute die are stacked over the memory stack.

Example embodiment 3: The processor package module of embodiment 1, wherein the memory stack is stacked over the one or more compute die.

Example embodiment 4: The processor package module of embodiment 1, 2 or 3, wherein the memory stack comprises an array of stacked memory die.

Example embodiment 5: The processor package module of embodiment 1, wherein the one or more photonic die are mounted on the substrate adjacent to the processor-memory stack.

Example embodiment 6: The processor package module of embodiment 5, wherein the one or more photonic die surround the processor-memory stack.

Example embodiment 7: The processor package module of embodiment 6, wherein the processor-memory stack has four sides and a respective photonic die is mounted to the substrate adjacent to each of the four sides.

Example embodiment 8: The processor package module of embodiment 1, wherein the one or more photonic die are mounted on the processor-memory stack adjacent to the one or more computer die.

Example embodiment 9: The processor package module of embodiment 1, 2, 3, 4, 5, 6, 7, or 8, wherein the socket housing comprises a land grid array (LGA) socket.

Example embodiment 10: A processor chip complex comprising a processor board and an array of processor package modules mounted to the processor board. Ones of the processor package modules comprise a processor-memory stack comprising one or more compute die stacked and interconnected with a memory stack on a substrate. One or more photonic die is on the board to transmit and receive optical I/O, the one or more photonic die connected to the processor-memory stack, wherein each of the one or more photonic die is coupled to a fiber array and an optical connector. The board is mounted onto a socket housing, and the socket mounts a corresponding processor package module to a front side of the processor board. The processor package modules are coupled to adjacent ones of the processor package modules in the array using the optical connectors.

Example embodiment 11: The processor chip complex of embodiment 10, wherein the socket housing comprises a land grid array (LGA) socket.

Example embodiment 12: The processor chip complex of embodiment 10 or 11, wherein the optical connectors of adjacent ones of the processor package modules are coupled together on a backside of the processor board.

Example embodiment 13: The processor chip complex of embodiment 10, 11, or 12, wherein fiber arrays of adjacent ones of the processor package modules are routed from the front side of the processor board to the backside of the processor board through holes in the processor board.

Example embodiment 14: The processor chip complex of embodiment 13, wherein the processor board includes a single hole between two adjacent processor package modules to route the fiber arrays to the backside of the processor board.

Example embodiment 15: The processor chip complex of embodiment 13, wherein the processor board includes two holes between two adjacent processor package modules, wherein a first of the two holes routes the fiber array from a first one of the two adjacent processor package modules, and a second of the two holes routes the fiber array from the second one of the two adjacent processor package modules.

Example embodiment 16: The processor chip complex of embodiment 10, 11, 12, 13, 14, or 15, further comprising a laser source mounted to the processor board to supply optical signals to the processor package modules.

Example embodiment 17: The processor chip complex of embodiment 16, wherein the laser source is mounted to a backside of the processor board and coupled to at least one of the fiber arrays.

Example embodiment 18: The processor chip complex of embodiment 16, wherein the laser source is mounted to the front side of the processor board and coupled to at least one of the fiber arrays.

Example embodiment 19: The processor chip complex of embodiment 10, 11, 12, 13, 14, 15, 16, 17, or 18, further comprising a power supply mounted to the processor board to supply power to the processor package modules.

Example embodiment 20: The processor chip complex of embodiment 19, wherein the power supply is mounted to a backside of the processor board.

Example embodiment 21: The processor chip complex of embodiment 19, wherein the power supply is mounted to the front side of the processor board.

Example embodiment 22: A method of fabricating a patch structure comprises fabricating a plurality of processor package modules using standard assembly processes, ones of the processor package modules comprising a processor-memory module stack having one or more compute die stacked and interconnected with a memory on a substrate along with one or more photonic die. The processor package modules are mounted into respective LGA sockets. The processor package modules are tested to provide pretested processor package modules. The pretested processor package modules are mounted to a front side of a processor board in an array using the LGA sockets, and power is supplied to each of the pretested processor package modules through the LGA sockets from a backside of the processor board. Adjacent ones of the pretested processor package modules are optically connected using optical fiber connections on the backside of the processor board to form the processor chip complex.

Example embodiment 23: The method of embodiment 22, further comprising making optical fiber connections between at least a portions of the processor package modules located along one or more edges of the array to components external to the processor chip complex.

Example embodiment 24: The method of embodiment 22 or 23, wherein fabricating the plurality of processor package modules further comprises mounting a respective photonic die adjacent to each side of the processor board.

Example embodiment 25: The method of embodiment 22, 23 or 24, wherein fabricating the plurality of processor package modules further comprises mounting the one or more photonic die on the processor-memory stack.

What is claimed is:

1. A processor package module, comprising:
a substrate;
a processor-memory stack comprising one or more compute die stacked and interconnected with a memory stack on the substrate;
one or more photonic die on the substrate to transmit and receive optical I/O, the one or more photonic die connected to the processor-memory stack and connected to external components through a fiber array; and
a socket housing onto which the substrate is mounted.

2. The processor package module of claim 1, wherein the one or more compute die are stacked over the memory stack.

3. The processor package module of claim 1, wherein the memory stack is stacked over the one or more compute die.

4. The processor package module of claim 1, wherein the memory stack comprises an array of stacked memory die.

5. The processor package module of claim 1, wherein the one or more photonic die are mounted on the substrate adjacent to the processor-memory stack.

6. The processor package module of claim 5, wherein the one or more photonic die surround the processor-memory stack.

7. The processor package module of claim 6, wherein the processor-memory stack has four sides and a respective photonic die is mounted to the substrate adjacent to each of the four sides.

8. The processor package module of claim 1, wherein the one or more photonic die are mounted on the processor-memory stack adjacent to the one or more computer die.

9. The processor package module of claim 1, wherein the socket housing comprises a land grid array (LGA) socket.

10. A processor chip complex, comprising:
a processor board;
an array of processor package modules mounted to the processor board, ones of the processor package modules comprising:
a processor-memory stack comprising one or more compute die stacked and interconnected with a memory stack on a substrate;
one or more photonic die on the substrate to transmit and receive optical I/O, the one or more photonic die connected to the processor-memory stack, wherein each of the one or more photonic die is coupled to a fiber array and an optical connector; and
a socket housing onto which the substrate is mounted, the socket mounting a corresponding processor package module to a front side of the processor board;
wherein the processor package modules are coupled to adjacent ones of the processor package modules in the array using the optical connectors.

11. The processor chip complex of claim 10, wherein the socket housing comprises a land grid array (LGA) socket.

12. The processor chip complex of claim 10, wherein the optical connectors of adjacent ones of the processor package modules are coupled together on a backside of the processor board.

13. The processor chip complex of claim 12, wherein fiber arrays of adjacent ones of the processor package modules are routed from the front side of the processor board to the backside of the processor board through holes in the processor board.

14. The processor chip complex of claim 13, wherein the processor board includes a single hole between two adjacent processor package modules to route the fiber arrays to the backside of the processor board.

15. The processor chip complex of claim 13, wherein the processor board includes two holes between two adjacent processor package modules, wherein a first of the two holes routes the fiber array from a first one of the two adjacent processor package modules, and a second of the two holes routes the fiber array from the second one of the two adjacent processor package modules.

16. The processor chip complex of claim 10, further comprising a laser source mounted to the processor board to supply optical signals to the processor package modules.

17. The processor chip complex of claim 16, wherein the laser source is mounted to a backside of the processor board and coupled to at least one of the fiber arrays.

18. The processor chip complex of claim 16, wherein the laser source is mounted to the front side of the processor board and coupled to at least one of the fiber arrays.

19. The processor chip complex of claim 10, further comprising a power supply mounted to the processor board to supply power to the processor package modules.

20. The processor chip complex of claim 19, wherein the power supply is mounted to a backside of the processor board.

21. The processor chip complex of claim 19, wherein the power supply is mounted to the front side of the processor board.

22. A method of fabricating a patch structure, the method comprising:
fabricating a plurality of processor package modules using standard assembly processes, ones of the processor package modules comprising a processor-memory module stack having one or more compute die stacked and interconnected with a memory on a substrate along with one or more photonic die;
mounting the processor package modules into respective LGA sockets;
testing the processor package modules to provide pretested processor package modules;
mounting the pretested processor package modules to a front side of a processor board in an array using the LGA sockets, and supplying power to each of the pretested processor package modules through the LGA sockets from a backside of the processor board; and
optically connecting adjacent ones of the pretested processor package modules using optical fiber connections on the backside of the processor board to form the processor chip complex.

23. The method of claim 22, further comprising making optical fiber connections between at least a portions of the processor package modules located along one or more edges of the array to components external to the processor chip complex.

24. The method of claim 22, wherein fabricating the plurality of processor package modules further comprises mounting a respective photonic die adjacent to each side of the processor board.

25. The method of claim 22, wherein fabricating the plurality of processor package modules further comprises mounting the one or more photonic die on the processor-memory stack.
